(19) United States
(12) Patent Application Publication
(10) Pub. No.: US 2011/0074226 A1
(43) Pub. Date: Mar. 31, 2011

(54) POWER CONTROLLER, ELECTRONIC APPARATUS AND POWER CONTROL METHOD

(75) Inventor: Katsuya OHNO, Kokubunji-shi (JP)

(73) Assignee: KABUSHIKI KAISHA TOSHIBA, Tokyo (JP)

(21) Appl. No.: 12/893,774

(22) Filed: Sep. 29, 2010

(30) Foreign Application Priority Data
Sep. 29, 2009 (JP) 2009-223696

(51) Int. Cl. H03K 17/00

(52) U.S. Cl. 307/125

(57) ABSTRACT

A power controller for controlling a power supply having a predetermined voltage, generated based on a power supplied from an external power source and supplied to a signal processor, includes: a receiver configured to receive a signal for switching an ON/OFF state of the power supply from a remote controller, a controller configured to switch the ON/OFF state of the power supply depending on the signal received by the receiver, and a communication module configured to communicate with the signal processor that operates when the controller switches the power supply to be in an ON state, wherein the controller controls to make the communication module be non-operational when the power supply is in an OFF state and to make the communication module be operational when the power supply is in an ON state.

### CROSS-REFERENCE TO RELATED APPLICATION

This application is based on and claims priority under U.S.C. §119 from Japanese Patent Application No. 2009-223696 filed on Sep. 29, 2009.

### BACKGROUND

1. Field

One embodiment of the invention relates to a power controller, an electronic apparatus and a power control method for controlling to turn on/off the power supply.

2. Description of the Related Art

In some cases, an electronic apparatus, such as a television receiver or an HDD recorder, has, as the states thereof, an operation state in which almost all the functional modules thereof can operate and a standby state in which the main functional modules thereof do not operate but only functions, such as receiving control signals from a remote controller and time keeping, operate.

Moreover, in recent years, it is expected to reduce the power consumption (also referred to as standby power) of an electronic apparatus in the standby state thereof, and various methods for fulfilling this expectation have been proposed.

For example, Japanese Patent Application Publication No. 2000-047764 discloses a method in which, in a configuration including a small-sized standby microcomputer having low power consumption and mainly used to receive signals from a remote controller and a high-speed main microcomputer for controlling a television receiver as individual microcomputers, voltage supply to the main microcomputer is turned off in the standby state so that only the standby microcomputer operates, thereby reducing standby power.

In addition, Japanese Utility Model No. 3072612 discloses a method in which, upon receiving a power OFF command through operation of a remote controller, a video control apparatus and a television receiver stop the clock of a microcomputer for executing various processes, thereby reducing standby power.

However, according to Japanese Patent Application Publication No. 2000-047764 (FIG. 1, paragraph [0027]), power is supplied to the standby microcomputer in the standby state. Even if the standby microcomputer is a small-sized microcomputer featuring low power consumption during power-on time, there still remains room for improvement in reducing standby power.

Moreover, according to Japanese Utility Model No. 3072612 (FIG. 4, paragraph [0017]), during power-off time, the clock is stopped, but power remains supplied to the microcomputer. For this reason, it cannot be expected to reduce the power consumption of the microcomputer, and it is difficult to say that standby power has been reduced sufficiently. Furthermore, reducing the standby power of an optical receiver for receiving signals from the remote controller is not taken into consideration.

That is to say, conventionally, it is impossible to maintain the state of reducing standby power for a long time.

### BRIEF DESCRIPTION OF THE DRAWINGS

A general architecture that implements the various features of the invention will now be described with reference to the drawings. The drawings and the associated descriptions are provided to illustrate embodiments of the invention and not limited the scope of the invention.

FIG. 1 is an exemplary block diagram showing the configuration of a television receiver being used as an electronic apparatus equipped with a power controller according to a first embodiment of the present invention;

FIG. 2 is an exemplary block diagram showing the configuration of a system formed of respective modules for executing a power supply control process and an operation control process according to the first embodiment;

FIG. 3 is an exemplary table comparatively showing the outputs, states and operations of the respective modules according to the first embodiment described referring to FIG. 2 in the power supply control process executed using the respective modules;

FIG. 4 is an exemplary block diagram showing the configuration of a system formed of respective modules for executing a power supply control process and an operation control process according to a second embodiment;

FIG. 5 is an exemplary table comparatively showing the outputs, states and operations of the respective modules according to the second embodiment described referring to FIG. 4 in the power supply control process executed using the respective modules;

FIG. 6 is an exemplary block diagram showing the configuration of a system formed of respective modules for executing a power supply control process and an operation control process according to a third embodiment; and

FIG. 7 is an exemplary table comparatively showing the outputs, states and operations of respective modules according to the third embodiment described referring to FIG. 6 in the power supply control process executed using the respective modules.

### DETAILED DESCRIPTION

Various embodiments according to the invention will be described hereinafter with reference to the accompanying drawings.

In general, according to one embodiment, a power controller for controlling a power supply having a predetermined voltage, generated based on a power supplied from an external power source and supplied to a signal processor, includes: a receiver configured to receive a signal for switching an ON/OFF state of the power supply from a remote controller, a controller configured to switch the ON/OFF state of the power supply depending on the signal received by the receiver, and a communication module configured to communicate with the signal processor that operates when the controller switches the power supply to be in an ON state. The controller controls to make the communication module be non-operational when the power supply is in an OFF state and to make the communication module be operational when the power supply is in an ON state.

### First Embodiment

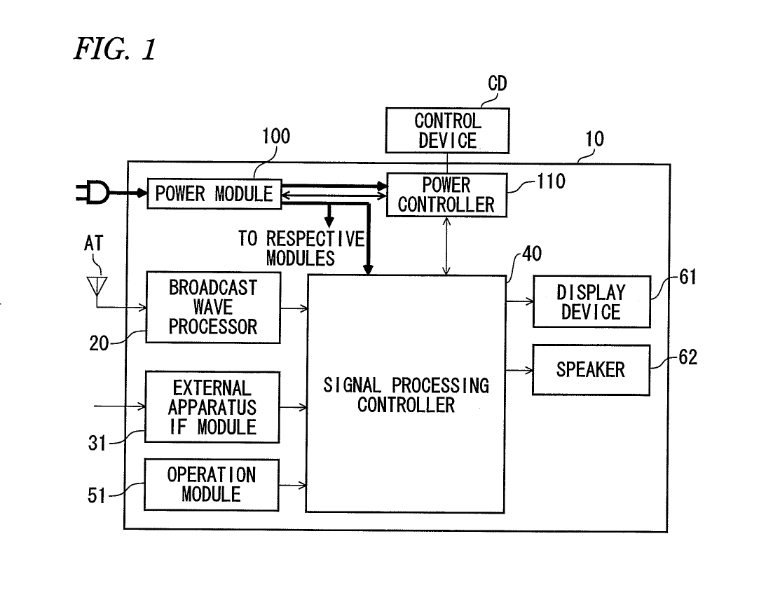

FIG. 1 is an exemplary block diagram showing the configuration of a television receiver 10 being used as an electronic apparatus equipped with a power controller according to a first embodiment of the present invention.

The television receiver 10 according to the first embodiment includes a broadcast wave processor 20, an external apparatus IF module 31, a signal processing controller 40, an operation module 51, a display device 61, a speaker 62, a power module 100, a power controller 110, etc. Furthermore, an antenna ANT is connected to the broadcast wave processor 20, and the power module 100 is connected to a household outlet or the like. Moreover, the power controller 110 exchanges information with a control device CD. For example, the control device CD is a remote controller, such as an infrared remote controller or a wireless communication apparatus.

The television receiver 10 operates based on a power supplied from a household outlet or the like connected to the power module 100. Furthermore, the television receiver 10 switches an ON/OFF state of the power to be supplied to almost all the modules of the television receiver 10 depending on a signal that is input from the control device CD to turn on/off the power. Moreover, when almost all the modules of the television receiver 10 are non-operational since no power is supplied thereto, a specific module to which a specific power is supplied and which operates on the specific power is made be non-operational.

The power module 100 executes voltage conversion processes, such as AC/DC conversion and DC/DC conversion, based on the power supplied from a household outlet or the like to generate a power supply having a predetermined voltage. Then, the power module 100 supplies the power supply having the generated predetermined voltage to almost all the modules of the television receiver 10 including the signal processing controller 40. Furthermore, the power module 100 execute a power supply control process in which an ON/OFF state of the power supply having the predetermined voltage is switched based on a control signal input from the power controller 110. Moreover, the power module 100 charges a rechargeable battery based on the power supply having the predetermined voltage, thereby generating a charged power to be used as a power supply. While the power module 100 turns off the power supply having the predetermined voltage by means of the power supply control process, the power module 100 supplies the generated charged power to the power controller 110.

The power controller 110 exchanges information with the control device CD and communicates with the signal processing controller 40 according to this information. In addition, the power controller 110 outputs a control signal for switching an ON/OFF state of the power supply having the predetermined voltage to the power module 100 based on the information input from the control device CD. Besides, while the power module 100 turns off the power supply having the predetermined voltage, the power controller 110 operates on the charged power supplied from the power module 100 and executes an operation control process so that a specific module provided for the power controller 110 itself is made be non-operational. While the power module 100 turns on the power supply having the predetermined voltage, the power controller 110 operates on the predetermined voltage supplied from the power module 100.

Almost all the modules to be described hereafter operate on the predetermined voltage supplied from the power module 100. For this reason, while the power module 100 turns off the power supply having the predetermined voltage by means of the power supply control process, almost all the modules to be described hereafter do not operate.

The broadcast wave processor 20 has a tuner and a decoder adapted for terrestrial or satellite digital and analog broadcast waves received using the antenna ANT. The broadcast wave processor 20 obtains a signal received using the antenna ANT, performs a specific channel selection process and demodulation/decoding processes depending on this obtained signal, and outputs signals including video/audio information on a program, information relating to the program, etc. to the signal processing controller 40. The information relating to the program includes the channel number of the program, the broadcast wave for the program, the name of the broadcast station for the program, the title of the program, the genre of the program, etc.

The external apparatus IF module 31 is used for connection to, for example, external apparatuses of the television receiver 10 and recording media, such as an external HDD and a memory card, via the connection modules thereof conforming to various standards, such as the HDMI (registered trade name) standard, the USB standard and the IEEE 1394 standard. In addition, the external apparatus IF module 31 obtains signals including the video/audio information on a plurality of programs and information relating to the programs provided from the external apparatuses, recording media, etc. connected thereto and outputs the signals to the signal processing controller 40.

The operation module 51 receives operation input information for operating the television receiver 10 and outputs the information to the signal processing controller 40.

The signal processing controller 40 executes various processes, such as a decompression process for compressed data, and an information extraction process for creating a program schedule, for the information input from the broadcast wave processor 20, the external apparatus IF module 31, etc. based on the information, such as the operation input information, from the operation module 51 and the power controller 110. The signal processing controller 40 executes various processes, such as MPEG encoding/decoding arithmetic processes and video/audio signal separation processes, for the obtained information, and then outputs a video signal to the display device 61 and an audio signal to the speaker 62. Furthermore, the signal processing controller 40 is equipped with a CPU or a microcomputer (not shown) serving as a controller and controls the execution of a plurality of processes using respective modules provided for the signal processing controller 40 itself and respective modules connected to the signal processing controller 40 itself.

In the first embodiment, the signal processing controller 40 communicates with the power controller 110 depending on the operation input information exchanged between the power controller 110 and the control device CD and executes various processes corresponding to the operation input information from the control device CD. In addition, the signal processing controller 40 operates on the predetermined voltage supplied from the power module 100 as described above. However, when the power module 100 turns off the power supply having the predetermined voltage, the signal processing controller 40 cannot operate and thus cannot communicate with the power controller 110.

The display device 61 is a display module for displaying the video signal input from the signal processing controller 40. For example, the display device 61 is a thin display, such as a liquid crystal display (hereafter also referred to as an LCD) or a PDP (plasma display panel).

The speaker 62 outputs the audio signal input from the signal processing controller 40.

In the first embodiment, the television receiver is taken as an example of an electronic apparatus equipped with the power controller to which the configuration according to the present invention is applied. However, an electronic apparatus, such as an HDD recorder, a DVD recorder, a personal computer or a mobile terminal, having a structure similar to that of the electronic apparatus according to the first embodiment may also be taken as an example of the electronic apparatus. Furthermore, a set top box serving as a video output apparatus for receiving not only television broadcast and satellite broadcast but also radio broadcast, cable broadcast using the Internet, etc. and for outputting video signals may also be taken as an example of the electronic apparatus.

With this configuration, the respective modules of the television receiver 10 according to the first embodiment of the present invention operate on the two kinds of powers supplied via the power module 100. Moreover, the standby power of the television receiver 10 can be reduced by executing a process for turning on/off the power supply that is one of the two kinds of powers and supplied to the almost all the modules. Still further, when the power supply is turned off, a process for making a specific module operating on the other power be non-operational is executed. Hence, the standby state can be maintained for a long time.

In addition, these processes are executed mainly using the power controller 110 based on the powers supplied via the power module 100.

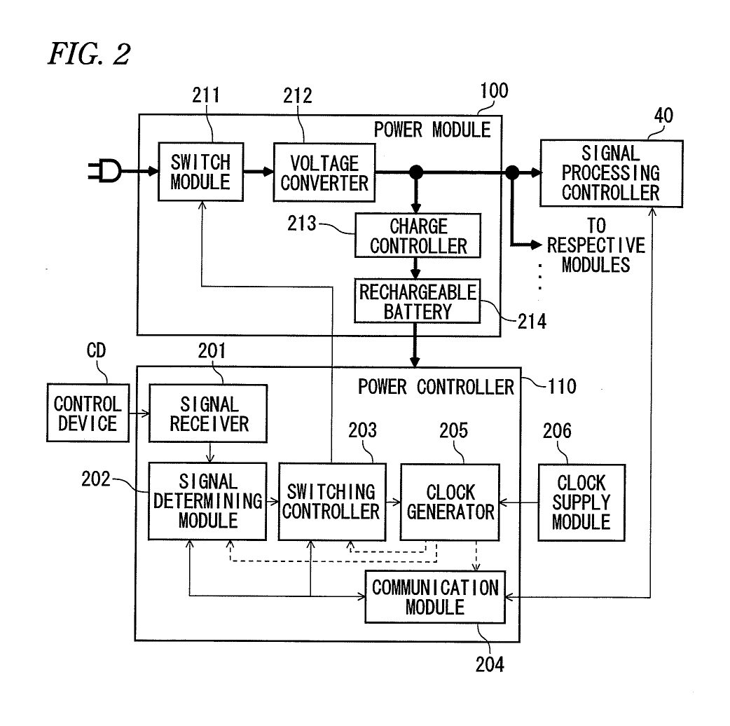

Next, respective modules provided for the power module 100 and the power controller 110 described referring to FIG. 1 to execute the power supply control process and the operation control process will be described below referring to FIG. 2.

FIG. 2 is an exemplary view showing the configuration of a system formed of the respective modules for executing the power supply control process and the operation control process according to the first embodiment.

As described above, the power supply control process is a process in which the power module 100 switches an ON/OFF state of the power supply having the predetermined voltage based on the control signal input from the power controller 110. Furthermore, the operation control process is a process in which, when the power supply having the predetermined voltage is controlled so as to be turned off, the power controller 110 makes the specific module provided for the power controller 110 itself be non-operational.

The power module 100 according to the first embodiment is equipped with a switch module 211, a voltage converter 212, a charge controller 213, a rechargeable battery 214, etc. In addition, the power controller 110 according to the first embodiment is equipped with a signal receiver 201, a signal determining module 202, a switching controller 203, a communication module 204, a clock generator 205, etc. This clock generator 205 is connected to a clock supply module 206.

First, the respective modules provided for the power module 100 will be described below.

The switch module 211 is formed of a switch for opening/closing a power supply path for supplying the power to the signal processing controller 40. Based on information input from the switching controller 203, the switch module 211 opens/closes the power supply path. For example, a relay and a mechanical switch can be used as the switch module 211. However, in the first embodiment, a configuration in which a relay is used as the switch module 211 is taken as an example and described below.

The voltage converter 212 subjects the power supplied via the switch module 211 to voltage conversion processes, such as AC/DC conversion and DC/DC conversion, and supplies the predetermined voltage generated by having been subjected to the voltage conversion processes to the charge controller 213. In addition, the voltage converter 212 also supplies the predetermined voltage to the respective modules of the television receiver 10.

When the power supply having the predetermined voltage is turned on, the charge controller 213 charges the rechargeable battery 214 based on the power supply having the predetermined voltage supplied from the voltage converter 212. However, even if the power supply having the predetermined voltage is turned on, when the rechargeable battery 214 is fully charged, the charge controller 213 stops the execution of the charging process. The charge controller 213 also stops the execution of the charging process when the power supply having the predetermined voltage is turned off.

The rechargeable battery 214 is a charged power that is charged by the charging process executed using the charge controller 213 when the power supply having the predetermined voltage is turned on and that is used as a power when the power supply having the predetermined voltage is turned off. In other words, when the power supply having the predetermined voltage is turned off, the rechargeable battery 214 serves as a charged power and the charged power is supplied to the respective modules of the power controller 110. Furthermore, when the power supply having the predetermined voltage is turned on, the rechargeable battery 214 is not used as a power but is charged by the charging process under the control of the charge controller 213. When fully charged, the rechargeable battery 214 operates to supply the predetermined voltage. For example, an electric double layer capacitor having a predetermined capacitance can be used as the rechargeable battery 214.

Next, the respective modules provided for the power controller 110 will be described below.

The signal receiver 201 receives a signal relating to operation input for operating the television receiver 10 and transmitted from the control device CD. Then, the signal receiver 201 subjects the received signal to a predetermined process to obtain information, and outputs the information to the signal determining module 202. For example, when the control device CD is an infrared remote controller, the signal receiver 201 subjects an infrared signal transmitted from the control device CD to photoelectric conversion to obtain information, and outputs the information obtained by the conversion to the signal determining module 202. Furthermore, the signal receiver 201 may transmit, for example, information indicating the state of the television receiver 10, to the control device CD.

The signal determining module 202 determines the information input from the signal receiver 201 and outputs determination information corresponding to the result of the determination depending on the result of the determination to the switching controller 203 or the communication module 204. More specifically, when the input information is determined as information for controlling an ON/OFF state of the power supply to the specific module of the television receiver 10, the signal determining module 202 outputs this determination information to the switching controller 203. Furthermore, a predetermined clock is supplied from the clock generator 205 to the signal determining module 202. The signal determining module 202 may directly output the determination information to the signal processing controller 40 instead of outputting to the switching controller 203 or the communication module 204.

Based on the determination information input from the signal determining module 202 or the information input from the communication module 204, the switching controller 203 outputs switching information for controlling to open/close the power supply path to the switch module 211 and the clock generator 205. In addition, a predetermined clock is supplied from the clock generator 205 to the switching controller 203.

The communication module 204 communicates with a controller (not shown) provided for the signal processing controller 40 based on the determination information input from the signal determining module 202. In addition, the communication module 204 outputs the information communicated with the controller (not shown) provided for the signal processing controller 40 to the signal determining module 202 or the switching controller 203. A predetermined clock is supplied from the clock generator 205 to the communication module 204.

Based on a clock supplied from the clock supply module 206, the clock generator 205 executes frequency division, etc. to generate a plurality of clocks and supplies the clocks to the respective modules provided for the power controller 110. Furthermore, the clock generator 205 controls the supply/non-supply of the predetermined clocks based on the switching information input from the switching controller 203. More specifically, when the switching information for opening the power supply path is input from the switching controller 203, the clock generator 205 controls to stop the supply of the clock to the communication module 204. Conversely, when the switching information for closing the power supply path is input from the switching controller 203, the clock generator 205 controls to supply the clock to the communication module 204.

The clock supply module 206 generates a predetermined clock by means of an oscillation circuit using an oscillation device, such as a crystal or ceramic oscillator, and supplies this clock to the clock generator 205. Although the clock supply module 206 is disposed outside the power controller 110 in the first embodiment, the clock supply module 206 may be configured such that part of the oscillation circuit thereof is disposed inside the power controller 110.

In other words, based on the switching information input from the power controller 110 having received a signal from the control device CD, the power module 100 switches an ON/OFF state of the power supply having the predetermined voltage. Furthermore, when the switching controller 203 controls so that the switch module 211 opens the power supply path, that is, when control is executed so that the power supply having the predetermined voltage is turned off, the power controller 110 stops supplying the clock to the communication module 204 provided for the power controller 110 itself, thereby making the communication module 204 be non-operational.

With this system configuration, the power controller 110 according to the first embodiment of the present invention is configured so as to serve as a power controller. Furthermore, the power controller 110 executes the power supply control process for the respective powers supplied from the power module 100 and the operation control process for the power controller 110 itself. Hence, the state of reducing standby power can be maintained for a long time.

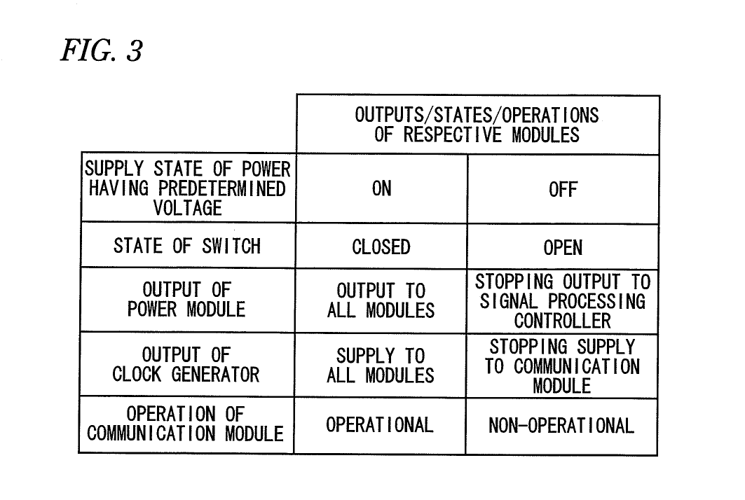

Next, in the power supply control process executed using the respective modules according to the first embodiment described referring to FIG. 2, the outputs, states and operations of the respective modules are described referring to FIG. 3.

FIG. 3 is an exemplary table comparatively showing the outputs, states and operations of the respective modules according to the first embodiment described referring to FIG. 2 in the power supply control process executed using the respective modules.

As described above, the power supply control process is a process in which the power module 100 switches an ON/OFF state of the power supply having the predetermined voltage based on the control signal input from the power controller 110.

In addition, when the power supply having the predetermined voltage is switched “ON” by the power supply control process, the switch module 211 “closes” the power supply path based on the switching information input from the switching controller 203 as shown in the table of FIG. 3. Furthermore, the power module 100 “outputs” the predetermined voltage and the charged power to “all the modules” of the television receiver 10. Moreover, the clock generator 205 “supplies” the generated plurality of clocks to “all the modules” provided for the power controller 110. As a result, the communication module 204 to which the charged power and the predetermined clock are supplied becomes “operational.”

On the other hand, when the power supply having the predetermined voltage is switched “OFF” by the power supply control process, the switch module 211 “opens” the power supply path based on the switching information input from the switching controller 203. In addition, the power module 100 does not supply the predetermined voltage to the respective modules of the television receiver 10. More specifically, the power module 100 “stops outputting the predetermined voltage to the signal processing controller 40.” Furthermore, the clock generator 205 supplies the generated plurality of clocks to not all the modules provided for the power controller 110 but stops supplying the predetermined clock to the specific module. That is to say, the clock generator 205 “stops supplying the predetermined clock to the communication module 204.” As a result, the communication module 204 to which the predetermined clock is not supplied becomes “non-operational.”

When the outputs, states and operations of the respective modules provided for the power module 100 and the power controller 110 are switched by the power supply control process and when the power supply having the predetermined voltage is switched off as described above, the state of reducing standby power can be maintained for a long time.

### Second Embodiment

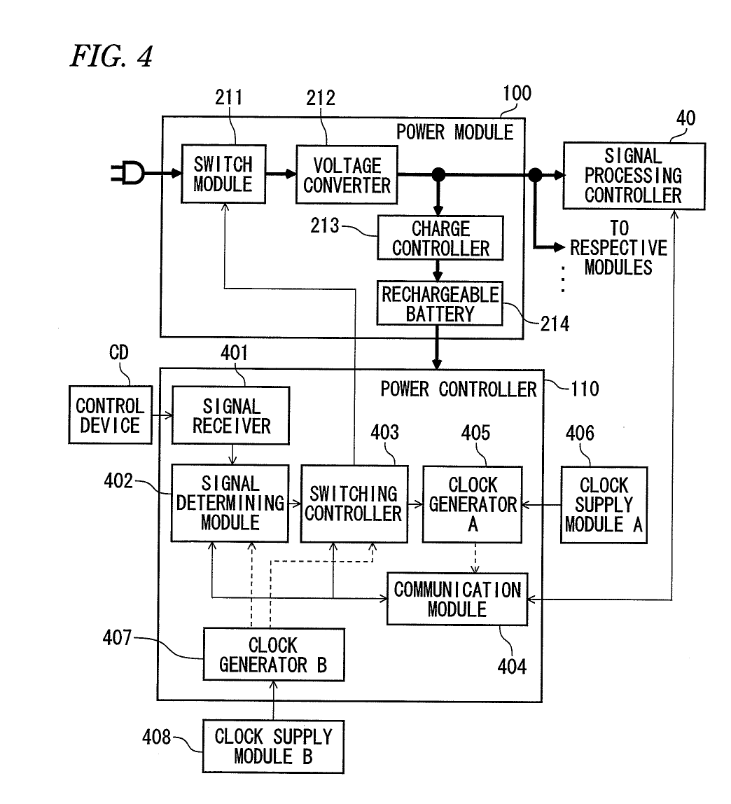

Next, respective modules provided for the power module 100 and the power controller 110 described referring to FIG. 1 to execute the power supply control process and the operation control process will be described below referring to FIG. 4.

FIG. 4 is an exemplary view showing the configuration of a system formed of the respective modules for executing the power supply control process and the operation control process according to a second embodiment.

The system configuration according to the second embodiment is different from the system configuration according to the first embodiment shown in FIG. 2 in that the power controller 110 is equipped with two clock generators A405 and B407 and two clock supply modules A406 and B408. Hereafter, the descriptions similar to those shown in the system configuration view of FIG. 2 are omitted or simplified, and main differences are described in detail.

The power module 100 according to the second embodiment is equipped with the switch module 211, the voltage converter 212, the charge controller 213, the rechargeable battery 214, etc. However, since these modules are the same as the respective modules according to the first embodiment shown in FIG. 2 in configuration, the detailed descriptions thereof are omitted.

Furthermore, the power controller 110 according to the second embodiment is equipped with a signal receiver 401, a signal determining module 402, a switching controller 403, a communication module 404, the clock generators A405 and B407, etc. The clock generator A405 is connected to the clock supply module A406, and the clock generator B407 is connected to the clock supply module B408.

Since the configurations and operations of the signal receiver 401, the signal determining module 402, the switching controller 403 and the communication module 404 are almost similar to those of the signal receiver 201, the signal determining module 202, the switching controller 203 and the communication module 204 shown in FIG. 2, the detailed descriptions thereof are omitted.

In other words, the switching controller 403 controls so that the switch module 211 provided for the power module 100 opens/closes the power supply path based on the determination information input from the signal determining module 402 depending on a signal regarding the power control of the television receiver 10 received by the signal receiver 401. In addition, the communication module 404 communicates with a controller (not shown) provided for the signal processing controller 40. Furthermore, predetermined clocks are supplied from the clock generator B407 to the signal determining module 402 and the switching controller 403, and a predetermined clock is supplied from the clock generator A405 to the communication module 404.

Based on a clock supplied from the clock supply module A406, the clock generator A405 executes frequency division, etc. to generate a predetermined clock and supplies the clock to the communication module 404. The clock generator A405 controls the supply/non-supply of the predetermined clock based on the switching information input from the switching controller 403. More specifically, when the switching information for opening the power supply path is input from the switching controller 403, the clock generator A405 controls to stop the supply of the clock to the communication module 404. Conversely, when the switching information for closing the power supply path is input from the switching controller 403, the clock generator A405 controls to supply the clock to the communication module 404.

Based on a clock supplied from the clock supply module B408, the clock generator B407 executes frequency division, etc. to generate predetermined clocks and supplies the clocks to the signal determining module 402 and the switching controller 403. The clock generator B407 generates the predetermined clocks without depending on the switching information output from the switching controller 403 and supplies the clocks to the respective modules.

The clock supply module A406 generates a predetermined clock by means of an oscillation circuit using an oscillation device, such as a crystal or ceramic oscillator, and supplies this clock to the clock generator A405. Similarly, the clock supply module B408 generates a predetermined clock by means of an oscillation circuit using an oscillation device, such as a crystal or ceramic oscillator, and supplies the clock to the clock generator B407. Although the clock supply modules A406 and B408 are disposed outside the power controller 110 in the second embodiment, the clock supply modules may be configured such that part of the oscillation circuit thereof is disposed inside the power controller 110.

In other words, also in the second embodiment, based on the switching information input from the power controller 110 having received a signal from the control device CD, the power module 100 switches an ON/OFF state of the power supply having the predetermined voltage. Furthermore, when the switching controller 403 controls so that the switch module 211 opens the power supply path, that is, when control is executed so that the power supply having the predetermined voltage is turned off, the power controller 110 stops supplying the clock to the communication module 404 provided for the power controller 110 itself, thereby making the communication module 404 be non-operational.

With this system configuration, the power controller 110 according to the second embodiment of the present invention is configured so as to serve as a power controller. Furthermore, the power controller 110 executes the power supply control process for the respective powers supplied from the power module 100 and the operation control process for the power controller 110 itself. Hence, the state of reducing standby power can be maintained for a long time.

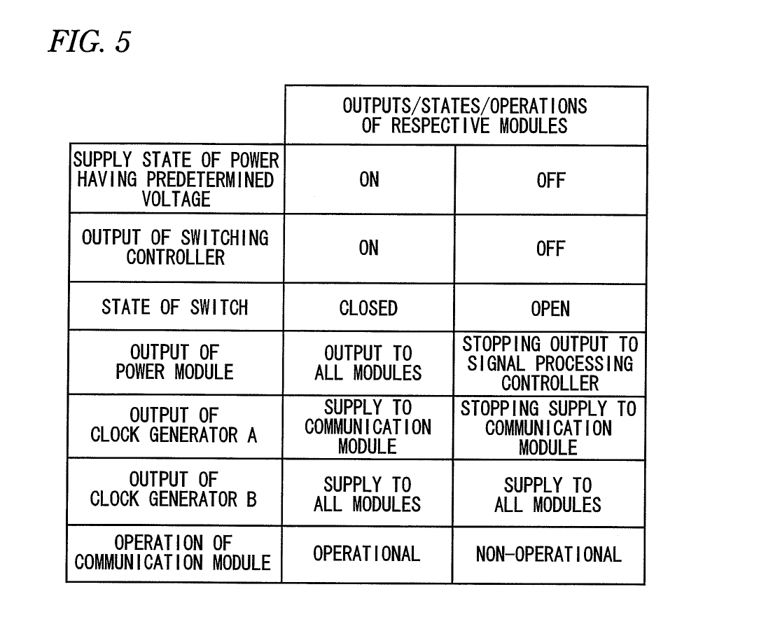

Next, in the power supply control process executed using the respective modules according to the second embodiment described referring to FIG. 4, the outputs, states and operations of the respective modules are described referring to FIG. 5.

FIG. 5 is an exemplary table comparatively showing the outputs, states and operations of the respective modules according to the second embodiment described referring to FIG. 4 in the power supply control process executed using the respective modules.

In addition, when the power supply having the predetermined voltage is switched “ON” by the power supply control process, the switch module 211 “closes” the power supply path based on the switching information input from the switching controller 403 as shown in the table of FIG. 5. Furthermore, the power module 100 “outputs” the predetermined voltage and the charged power to “all the modules” of the television receiver 10. Moreover, the clock generator A405 “supplies” the generated clock to the communication module 404, and the clock generator B407 “supplies” the generated plurality of clocks to “all” of the signal determining module 402 and the switching controller 403. As a result, the communication module 404 to which the charged power and the clock from the clock generator A405 are supplied becomes “operational.”

On the other hand, when the power supply having the predetermined voltage is switched “OFF” by the power supply control process, the switch module 211 “opens” the power supply path based on the switching information input from the switching controller 403. In addition, the power module 100 does not supply the predetermined voltage to the respective modules of the television receiver 10. More specifically, the power module 100 “stops outputting the predetermined voltage to the signal processing controller 40.” Furthermore, the clock generator A405 stops supplying the generated clock to the communication module 404. However, the clock generator B407 “supplies” the generated plurality of clocks to all of the signal determining module 402 and the switching controller 403. As a result, the communication module 404 to which no clock is supplied becomes “non-operational.”

Also in the second embodiment, when the outputs, states and operations of the respective modules provided for the power module 100 and the power controller 110 are switched by the power supply control process and when the power supply having the predetermined voltage is switched “OFF” as described above, the state of reducing standby power can be maintained for a long time.

### Third Embodiment

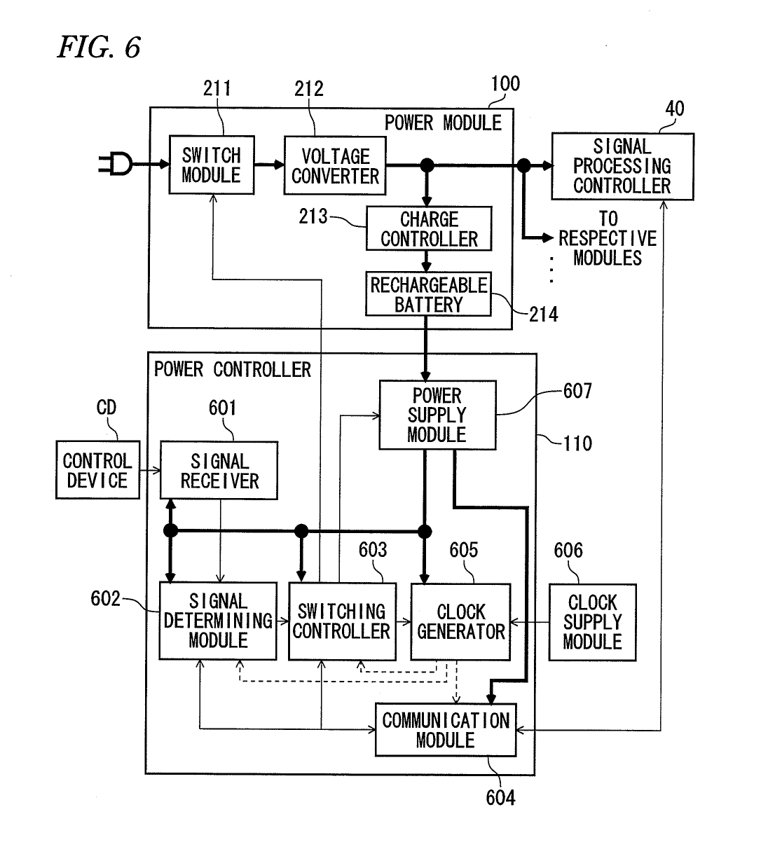

Next, respective modules provided for the power module 100 and the power controller 110 described referring to FIG. 1 to execute the power supply control process and the operation control process will be described below referring to FIG. 6.

FIG. 6 is an exemplary view showing the configuration of a system formed of the respective modules for executing the power supply control process and the operation control process according to a third embodiment.

The system configuration according to the third embodiment is different from the system configuration according to the first embodiment shown in FIG. 2 in that the power controller 110 is equipped with a power supply module 607. Hereafter, the descriptions similar to those shown in the system configuration view of FIG. 2 are omitted or simplified, and main differences are described in detail.

The power module 100 according to the third embodiment is equipped with the switch module 211, the voltage converter 212, the charge controller 213, the rechargeable battery 214, etc. However, since these modules are the same as the respective modules according to the first embodiment shown in FIG. 2 in configuration, the detailed descriptions thereof are omitted.

Furthermore, the power controller 110 according to the third embodiment is equipped with a signal receiver 601, a signal determining module 602, a switching controller 603, a communication module 604, a clock generator 605, the power supply module 607, etc. In addition, the clock generator 605 is connected to a clock supply module 606.

Since the configurations and operations of the signal receiver 601, the signal determining module 602, the switching controller 603 and the communication module 604 are almost similar to those of the signal receiver 201, the signal determining module 202, the switching controller 203 and the communication module 204 shown in FIG. 2, the detailed descriptions thereof are omitted.

In other words, the switching controller 603 controls so that the switch module 211 provided for the power module 100 opens/closes the power supply path based on the determination information input from the signal determining module 602 depending on a signal regarding the power control of the television receiver 10 received by the signal receiver 601. In addition, the communication module 604 communicates with a controller (not shown) provided for the signal processing controller 40. Furthermore, predetermined clocks are supplied from the clock generator 605 to the signal determining module 602, the switching controller 603 and the communication module 604.

Based on a clock supplied from the clock supply module 606, the clock generator 605 executes frequency division, etc. to generate a predetermined clock and supplies the clock to the signal determining module 602, the switching controller 603 and the communication module 604. The clock generator 605 generates the predetermined clocks without depending on the switching information output from the switching controller 603 and supplies the clocks to the respective modules.

The clock supply module 606 generates a predetermined clock by means of an oscillation circuit using an oscillation device, such as a crystal or ceramic oscillator, and supplies this clock to the clock generator 605. Although the clock supply module 606 is disposed outside the power controller 110 in the third embodiment, the clock supply module 606 may be configured such that part of the oscillation circuit thereof is disposed inside the power controller 110.

The power supply module 607 separates the charged power supplied from the rechargeable battery 214 provided for the power controller 110 into two powers and supplies the powers to the respective modules provided for the power controller 110. Furthermore, the power supply module 607 controls the supply/non-supply of one of the two powers based on the switching information input from the switching controller 603. More specifically, when the switching information for opening the power supply path is input from the switching controller 603, the power supply module 607 controls to stop the power supply to the communication module 604. Conversely, when the switching information for closing the power supply path is input from the switching controller 603, the power supply module 607 controls to supply the power to the communication module 604.

In other words, also in the third embodiment, based on the switching information input from the power controller 110 having received a signal from the control device CD, the power module 100 switches an ON/OFF state of the power supply having the predetermined voltage. Furthermore, when the switching controller 603 controls so that the switch module 211 opens the power supply path, that is, when control is executed so that the power supply having the predetermined voltage is turned off, the power controller 110 stops supplying the power to the communication module 604 provided for the power controller 110 itself, thereby making the communication module 604 be non-operational.

With this system configuration, the power controller 110 according to the third embodiment of the present invention is configured so as to serve as a power controller. Furthermore, the power controller 110 executes the power supply control process for the respective powers supplied from the power module 100 and the operation control process for the power controller 110 itself. Hence, the state of reducing standby power can be maintained for a long time.

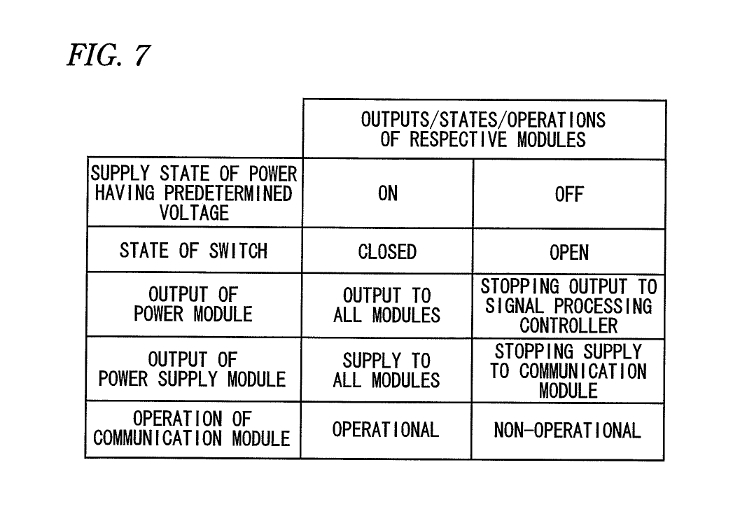

Next, in the power supply control process executed using the respective modules according to the third embodiment described referring to FIG. 6, the outputs, states and operations of the respective modules are described referring to FIG. 7.

FIG. 7 is an exemplary table comparatively showing the outputs, states and operations of the respective modules according to the third embodiment described referring to FIG. 6 in the power supply control process executed using the respective modules.

When the power supply having the predetermined voltage is switched “ON” by the power supply control process, the switch module 211 “closes” the power supply path based on the switching information input from the switching controller 603 as shown in the table of FIG. 7. Furthermore, the power module 100 “outputs” the predetermined voltage and the charged power to “all the modules” of the television receiver 10. Moreover, the power supply module 607 “supplies” the two separated charged powers to “all the modules” provided for the power controller 110. Still further, the clock generator 605 supplies the predetermined clocks to the respective modules provided for the power controller 110. As a result, the communication module 604 to which the charged power and the predetermined clock are supplied becomes “operational.”

On the other hand, when the power supply having the predetermined voltage is switched “OFF” by the power supply control process, the switch module 211 “opens” the power supply path based on the switching information input from the switching controller 603. In addition, the power module 100 does not supply the predetermined voltage to the respective modules of the television receiver 10. More specifically, the power module 100 “stops outputting the predetermined voltage to the signal processing controller 40.” Furthermore, the power supply module 607 supplies the two separated charged powers to not all the modules provided for the power controller 110, but stops supplying one of the powers to a specific module. That is to say, the power supply module 607 “stops supplying one of the powers to the communication module 604.” As a result, the communication module 404 to which the power is not supplied becomes “non-operational.”

Also in the third embodiment, when the outputs, states and operations of the respective modules provided for the power module 100 and the power controller 110 are switched by the power supply control process and when the power supply having the predetermined voltage is switched “OFF” as described above, the state of reducing standby power can be maintained for a long time.

As described above, according to the first to third embodiments of the present invention, based on the switching information input from the power controller 110 having received a signal from the control device CD, the power module 100 switches an ON/OFF state of the power supply having the predetermined voltage. Furthermore, when the switching controller 203 (403, 603) controls so that the switch module 211 opens the power supply path, that is, when control is executed so that the power supply having the predetermined voltage is turned off, the power controller 110 stops supplying the clock or the power to the communication module 204 (404, 604) provided for the power controller 110 itself, thereby making the communication module 204 (404, 604) be non-operational. Moreover, since the television receiver 10 is equipped with the power module 100 and the power controller 110, serving as a power controller for executing the above-mentioned processes, the state of reducing the standby power of the television receiver 10 can be maintained for a long time.

Furthermore, the present invention is not limited to the above-mentioned embodiments but can be changed and modified variously within the scope of not departing from the spirit of the present invention.

The invention is not limited to the foregoing embodiments but various changes and modifications of its components may be made without departing from the scope of the present invention. Also, the components disclosed in the embodiments may be assembled in any combination for embodying the present invention. For example, some of the components may be omitted from all the components disclosed in the embodiments. Further, components in different embodiments may be appropriately combined.

What is claimed is:

1. A power controller for controlling a power supply having a predetermined voltage, generated based on a power supplied from an external power source and supplied to a signal processor, comprising:
a receiver configured to receive a signal for switching an ON state and OFF state of the power supply from a remote controller,
a controller configured to switch between the ON state and the OFF state of the power supply depending on the signal received by the receiver, and
a communication module configured to communicate with the signal processor, the signal processor being configured to operate when the controller switches the power supply to be in an ON state, wherein
the controller is configured to control the communication module to be non-operational when the power supply is in an OFF state, and to control the communication module to be operational when the power supply is in an ON state.

2. The power controller of claim 1, wherein
the receiver and the controller are configured to operate by a rechargeable battery if the power supply is in the OFF state, the rechargeable battery being charged based on a power of the power supply while the power supply is in the ON state.

3. The power controller of claim 2, wherein
the controller is provided on a power supply path at a position substantially close to the external power source, and configured to control the ON state and the OFF state of the power supply by opening and closing the power supply path in which predetermined voltage conversion is not yet executed for the power supply.

4. The power controller of claim 2, wherein
the controller is configured to stop a supply of a clock to the communication module to control the communication module to be non-operational.

5. The power controller of claim 2, wherein
the controller is configured to stop a power supply to the communication module to control the communication module to be non-operational.

6. An electronic apparatus comprising:
a signal processor, and
a power controller for controlling a power supply having a predetermined voltage, generated based on a power supplied from an external power source and supplied to the signal processor,
the power controller comprising:
a receiver configured to receive a signal for switching an ON state and an OFF state of the power supply from a remote controller,
a controller configured to switch between the ON state and the OFF state of the power supply depending on the signal received by the receiver, and
a communication module configured to communicate with the signal processor, the signal processor being configured to operate when the controller switches the power supply to be in an ON state, wherein
the controller is configured to control the communication module to be non-operational when the power supply is in an OFF state, and to control the communication module to be operational when the power supply is in an ON state.

7. A power control method for controlling a power supply having a predetermined voltage, generated based on a power supplied from an external power source and supplied to a signal processor,
the method comprising:
receiving a signal for switching an ON state and an OFF state of the power supply from a remote controller,
switching between the ON state and the OFF state of the power supply depending on the received signal,
communicating with the signal processor, the signal processor being configured to operate when the power supply is switched to be in an ON state, and
controlling the communication to be non-operational when the power supply is in an OFF state, and controlling the communication to be operational when the power supply is in an ON state.
